(19) United States
(12) Patent Application Publication
(10) Pub. No.: US 2025/0024689 A1
(43) Pub. Date: Jan. 16, 2025

(54) TWO TERMINAL SPIN-ORBIT TORQUE MAGNETORESISTIVE RANDOM ACCESS MEMORY AND METHOD OF MANUFACTURING THE SAME

(71) Applicants: SAMSUNG ELECTRONICS CO., LTD., Suwon-si (KR); The Board of Trustees of the Leland Stanford Junior University, Stanford, CA (US)

(72) Inventors: William San-Hsi HWANG, Seattle, WA (US); Shan Xiang WANG, Portola Valley, CA (US); Fen Xue, Palo Alto, CA (US); Wilman TSAI, Saratoga, CA (US); Harsono SIMKA, Saratoga, CA (US)

(73) Assignees: SAMSUNG ELECTRONICS CO., LTD., Suwon-si (KR); The Board of Trustees of the Leland Stanford Junior University, Stanford, CA (US)

(21) Appl. No.: 18/767,862

(22) Filed: Jul. 9, 2024

Related U.S. Application Data
(60) Provisional application No. 63/525,800, filed on Jul. 10, 2023.

(51) Int. Cl. H10B 61/00; G01R 33/07; G01R 33/09; H10N 50/10; H10N 50/20

(52) U.S. Cl. CPC H10B 61/22; G01R 33/075; G01R 33/098; H10N 50/10; H10N 50/20

(57) ABSTRACT

An magnetoresistive random access memory (MRAM) device includes a magnetic tunnel junction, and a spin-orbit torque material. Based on a current applied to the spin-orbit torque material, the spin-orbit torque material generates spin polarization along one or multiple axes.

### CROSS-REFERENCE TO RELATED APPLICATION

This Application claims the benefit or priority from U.S. Provisional Application No. 63/525,800 filed Jul. 10, 2023 in the U.S. Patent and Trademark Office, the contents of which being herein incorporate by reference in its entirety.

### BACKGROUND

The present disclosure relates to a two terminal spin-orbit-torque (SOT) magnetoresistive random access memory (MRAM), and method for manufacturing the same.

The preponderance of artificial intelligence (AI) in modern society has enabled a wide range of transformative new applications in areas ranging from natural language processing to cancer diagnostics. State-of-the-art AI algorithms are trained in power-hungry, cloud datacenters, which impose extreme demands on the underlying computing hardware. Today's AI algorithms are highly memory intensive; for instance, GPT-3 includes ˜175 billion trainable parameters, which corresponds to a memory footprint which exceeds 700 gigabytes (assuming 32-bit data was used during training). As a result, enhancing the performance of the memory subsystem will play a key role in improving the overall energy-efficiency of tomorrow's computing systems.

The rise of big data and artificial intelligence (AI) has enabled transformative new technologies with a wide range of potential applications. Such rapid innovation has imposed extreme demands on the underlying computing fabric, where significant improvements in energy efficient computing hardware will be needed to keep pace with the demands of modern AI algorithms. In today's computing systems, state-of-the-art AI algorithms are trained in cloud datacenters, where heavy computing workloads necessitate the use of expensive, power-hungry computing hardware. For example, the training process for the GPT-3 language model, a predecessor of the GPT-3.5 and GPT-4 models that serve as the basis for the ubiquitous ChatGPT AI engine, is estimated to have consumed 1,287 MWh of energy. According to the U.S. Energy Information Administration, this amount of energy would be sufficient to power ˜1,500 US households for one month.

Today's mainstream AI applications rely heavily on application-specific architectures which include high throughput multiply-accumulate units fed by operands fetched from off-chip memories (generally DRAM today). For memory-intensive applications, studies have shown that a majority of program execution time and energy consumption (>90% in some cases) is spent accessing off-chip memories. As a result, enhancing the performance of the memory in conjunction to the computing logic is imperative to improving the overall energy-efficiency of tomorrow's computing systems.

### SUMMARY

It is an aspect to provide a non-volatile magnetoresistive random access memory device which achieves ultrahigh speed, density and energy efficiency.

It is another aspect to provide a non-volatile, high-speed, and high-capacity magnetoresistive random access memory collocated on-chip with computing logic.

According to an aspect of one or more embodiments, there is provided a magnetoresistive random access memory (MRAM) device comprising a magnetic tunnel junction; and a spin-orbit torque material. Based on a current applied to the spin-orbit torque material, the spin-orbit torque material generates spin polarization along one or multiple axes.

According to another aspect of one or more embodiments, there is provided a method of operating the magnetoresistive random access memory (MRAM) device including a magnetic tunnel junction; and a spin-orbit torque material, the method including applying the current to a spin-orbit torque material to generate spin polarization along one or multiple axes in the MRAM device.

According to yet another aspect of one or more embodiments, there is provided a method of operating the magnetoresistive random access memory (MRAM) device including a magnetic tunnel junction; and a spin-orbit torque material, the method including applying the current to the spin-orbit torque material to generate field-free switching in the MRAM device.

According to yet another aspect of one or more embodiments, there is provided a magnetoresistive random access memory (MRAM) device comprising an in-plane magnetic tunnel junction; and a spin-orbit torque material. Based on a current being applied to the spin-orbit torque material, the MRAM device switches field-free between a parallel state and an antiparallel state

According to yet another aspect of one or more embodiments, there is provided a magnetoresistive random access memory (MRAM) device comprising an out-of-plane magnetic tunnel junction; and a spin-orbit torque material. Based on a current being applied to the spin-orbit torque material, the MRAM device switches field-free between a parallel state and an antiparallel state.

According to yet another aspect of one or more embodiments, there is provided a method of manufacturing a two terminal spin-orbit torque (SOT) magnetoresistive random access memory (MRAM) device, the method comprising depositing a spin-orbit torque (SOT) material on a substrate; depositing a magnetic tunnel junction (MTJ) stack on the SOT material; forming a SOT line from the SOT material; forming an MTJ pillar from the MTJ stack; and forming a first electrode on the MTJ pillar and a second electrode on a portion of the SOT line.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates a structural configuration of a y-type two terminal SOT MRAM device using conventional SOT materials, according to some embodiments;

FIG. 2 illustrates the spin-orbit torque (SOT) in a conventional SOT material and the spin-transfer torque (STT), according to some embodiments;

FIGS. 3A and 3B illustrate a parallel state and antiparallel state of an in-plane magnetic tunnel junction (MTJ) and an out-of-plane MTJ, according to some embodiments;

FIG. 4 illustrates switching current verses MTJ critical dimension (CD) for a y-type and a z-type two terminal SOT MRAM device with conventional SOT material, according to some embodiments;

FIG. 5 illustrates switching current verses MTJ critical dimension (CD) for the y-type two terminal SOT MRAM device with conventional SOT material, according to some embodiments, as compared with an STT MRAM (z-type) device;

FIG. 6 illustrates write voltage versus the MTJ CD for the y-type two terminal SOT MRAM device with conventional SOT material, according to some embodiments, as compared with an STT MRAM (z-type) device;

FIG. 7 illustrates a bit cell area density of a y-type two terminal SOT MRAM device with conventional SOT material, according to some embodiments, in two fabrication processes as compared with an STT MRAM (z-type) device and a SRAM device;

FIG. 8 illustrates an example of a z-type two terminal SOT MRAM device with conventional or unconventional SOT material, according to some embodiments;

FIG. 9 illustrates the spin-orbit torque (SOT) and a tilt angle in an unconventional SOT material and the spin-transfer torque (STT), according to some embodiments;

FIG. 10 illustrates a simulation of non-deterministic operation in a z-type two terminal SOT MRAM device with an MTJ critical dimension (CD) of 30 nm and a conventional SOT material;

FIG. 11 illustrates a simulation of deterministic field-free switching in a z-type two terminal SOT MRAM device with an MTJ critical dimension (CD) of 26 nm and a conventional SOT material;

FIG. 12 illustrates an example bit cell layout of a z-type two terminal SOT MRAM with SOT material below the magnetic tunnel junction (MTJ), according to some embodiments;

FIG. 13 illustrates an example of a bit cell layout of a z-type two terminal SOT MRAM with SOT material above the MTJ, according to some embodiments;

FIG. 14 illustrates an example of a bit cell layout of a y-type two terminal SOT MRAM with SOT material below the MTJ, according to some embodiments;

FIG. 15 illustrates an example of a bit cell layout of an x-type two terminal SOT MRAM with SOT material below the MTJ, according to some embodiments;

FIG. 16A illustrates switching current in the z-type two terminal SOT MRAM for various unconventional SOT tilt angles according to some embodiments, with the switching current of pure STT MRAM (z-type) shown as a reference, and FIG. 16B illustrates voltage in the z-type two terminal SOT MRAM for various unconventional SOT tilt angles according to some embodiments, with the voltage of pure STT MRAM (z-type) shown as a reference;

FIG. 17 illustrates a resistance-area (RA) target in the z-type two terminal SOT MRAM for various unconventional SOT tilt angles according to some embodiments, with the RA target of pure STT MRAM (z-type) shown as a reference;

FIG. 18 illustrates magnetization trajectory along the z-axis as a function of time for a z-type two terminal SOT MRAM with unconventional SOT material, according to some embodiments;

FIG. 19 illustrates a flowchart of operation of a method of manufacturing a z-type two terminal SOT MRAM device having SOT material below the MTJ and perpendicular magnetic anisotropy, according to some embodiments;

FIGS. 20A to 20G illustrate the method of manufacturing the z-type two terminal SOT MRAM device having SOT material below the MTJ and perpendicular magnetic anisotropy, according to some embodiments;

FIG. 21 illustrates a block diagram illustrating an electronic system according to an embodiment;

FIG. 22 illustrates a block diagram illustrating a memory device of the electronic system of FIG. 21, according to an embodiment;

FIG. 23 illustrates a block diagram of a resistive memory device in the memory device of FIG. 22, according to some embodiments;

FIG. 24 illustrates an example of a first bank array in the resistive memory device of FIG. 23, according to some embodiments; and

FIG. 25 illustrates a circuit diagram illustrating an on-chip non-volatile memory according to an embodiment.

### DETAILED DESCRIPTION

As used in this specification, the phrase “at least one of A, B, or C” includes within its scope “only A”, “only B”, “only C”, “A and B”, “B and C”, “A and C”, and “A, B, and C.” It is noted that components in the drawings are not necessarily drawn to scale and some components may be exaggerated for clarity of description.

To date, a diverse range of non-volatile memory technologies have been proposed to help address the aforementioned memory bottleneck. For example, spin-orbit torque (SOT) memory is a non-volatile memory technology based on stacking magnetic tunnel junctions (MTJs) on SOT switching layers. The SOT switching layers may include materials such as heavy metals, topological materials, etc.

A SOT memory has desirable characteristics for use in high performance memory applications. For instance, SOT driven magnetization switching provides faster data operation in memory applications. A single write operation may be performed as fast as about 0.2 ns. This speed is comparable to related art semiconductor field-effect transistors used in static random access memory (SRAM). The SOT memory is nonvolatile and is significantly faster than competing memory technologies, such as spin-transfer torque (STT) (which has a switching speed of about 2 ns to about 10 ns), dynamic random access memory (DRAM) (which has a switching speed of about 30 to about 50 ns), resistive random access memory (RRAM) (which has a switching speed of about 100 ns), phase change memory (PCM) (which has a switching speed of about 150 ns) and flash memory (which has a switching speed of about 0.001 to about 1 ms).

According to various embodiments, two terminal SOT memory cells provide for high-density applications. According to various embodiments, SOT materials with unconventional spin polarizations and combination of SOT switching with other mechanisms such as spin-transfer torque (STT) or Voltage Controlled Magnetic Anisotropy (VCMA) may achieve high speed and high density.

According to various embodiments, a non-volatile magnetoresistive random access memory (MRAM) device may leverage a combination of spin-orbit torque (SOT) and spin-transfer torque (STT) in a two terminal device architecture and unconventional spin-orbit torque polarization, to achieve ultrahigh speed, density and energy efficiency. For example, the non-volatile magnetoresistive random access memory (MRAM) device may leverage a combination of spin-orbit torque (SOT) and spin-transfer torque (STT) in a two terminal device architecture to achieve ultrahigh speed, density and energy efficiency. More specifically, the two terminal SOT MRAM device may leverage the synergy between spin-transfer torque (STT) and spin-orbit torque (SOT) to enable field-free switching in a high-density bit cell layout.

As used in this specification, the terms “x-type”, “y-type”, and “z-type” refer to an easy axis anisotropy of a magnetic tunnel junction (MTJ), that is, a direction of magnetization of the MTJ. Thus, for example, a z-type two terminal SOT MRAM device refers to a two terminal SOT MRAM in which the magnetic tunnel junction thereof has an easy axis in the z-axis direction which is normal to a film deposition plane in an out-of-plane orientation, and thus has perpendicular magnetic anisotropy (PMA) and magnetization in the z-axis. As another example, a y-type two terminal SOT MRAM device refers to a two terminal SOT MRAM in which the MTJ thereof has an easy axis in the y-axis direction, and thus has in-plane magnetic anisotropy (IMA) and magnetization in the y-axis direction which is orthogonal to a direction of current flow in the SOT material and in the film deposition plane (e.g., an x-y plane). Similarly, an x-type two terminal SOT MRAM device refers to a two terminal SOT MRAM in which the MTJ thereof has an easy axis in the x-axis direction, and thus also has in-plane anisotropy (IMA) and magnetization in the x-axis direction which is parallel to the direction of current flow in the SOT material and in the film deposition plane (e.g., the z-y plane).

In the description that follows, the IMA device will be mainly described with reference to the y-type two terminal SOT MRAM device. However, embodiments are not limited thereto and one of ordinary skill in the art will understand that the description of the y-type two terminal SOT MRAM device may also apply to an x-type two terminal SOT MRAM device.

Emerging non-volatile memory technologies, such as SOT-based memories, pave one potential path towards improving the energy-efficiency at the hardware level. SOT memories use an electric current flowing through the high efficiency SOT material to generate a spin-orbit torque which can switch an adjacent magnetic free layer, such as CoFeB. In SOT memories that use an electric current flowing through the SOT material to generate spin-orbit torque to switch the adjacent magnetic free layer, the switching direction within the adjacent magnetic free layer may be in the in-plane orientation (e.g., in the case of a x-type device or y-type device) or in the perpendicular orientation (e.g., in the case of a z-type device) depending on the magnetic anisotropy of the device.

In the related art, in-plane MTJs have been thought to be unfavorable and impractical for two terminal STT MRAM applications because the required switching current is very high. For example, for an in-plane STT MRAM (x-type or y-type) for a MTJ with a critical dimension (CD) of about 10 nm to about 30 nm requires a switching current of 400 μA to about 1800 μA in order to achieve switching, in the case of a current pulse time of 0.5 ns. By contrast, a perpendicular STT (z-type) for an MTJ CD of about 22 nm to about 43 nm requires a switching current of only about 200 μA to about 750 μA to achieve switching for the same current pulse time. Thus, in the related art, the in-plane MTJ has generally been overlooked for STT MRAM applications due to the high current required for switching applications.

However, the inventors have found that, by adding a SOT material to the in-plane STT MRAM, the field-free switching operation becomes unexpectedly more favorable. Here, the term “field-free” is defined as a two terminal SOT MRAM device that is able to achieve deterministic operation and switching between the parallel and antiparallel states on its own without needing the assistance of an external magnetic field or bias field. The concept of “field-free” switching is discussed further below with reference to a z-type two terminal SOT MRAM device.

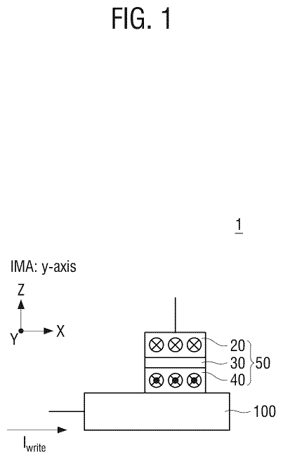

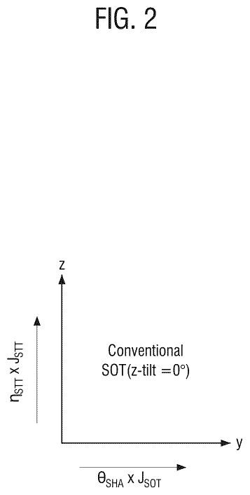

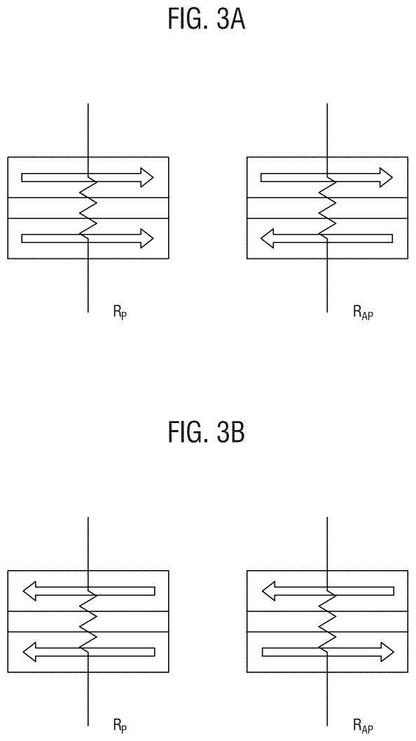

FIG. 1 illustrates a structural configuration of a y-type two terminal SOT MRAM device using conventional SOT materials, according to some embodiments. FIG. 2 illustrates the spin-orbit torque in a conventional SOT material and the spin-transfer torque (STT), according to some embodiments. FIG. 3A illustrates the parallel state and the antiparallel state of an in-plane magnetic tunnel junction (MTJ), according to some embodiments, and FIG. 3B illustrates the parallel state and the antiparallel state of an out-of-plane MTJ, according to some embodiments.

In FIG. 1, a y-type two terminal SOT MRAM device 1 may include a magnetic tunnel junction (MTJ) 50 and a spin-orbit torque (SOT) layer 100. The MTJ 50 may include a fixed magnetization layer 20, a tunnel barrier layer 30, and a magnetic free layer 40 in order from top to bottom in FIG. 1, such that an upper surface of the SOT layer 100 contacts the magnetic free layer 40. In an embodiment, a first terminal may be connected to the fixed magnetization layer 20 of the MTJ 50, and a second terminal may be connected to the SOT layer 100. The MTJ 50 has easy axis anisotropy along the y-axis (in-plane in the x-y plane) direction as described above. In other words, the MTJ 50 may be an in-plane magnetic tunnel junction, also known as a magnetic tunnel junction with an in-plane magnetic anisotropy (IMA) or with an in-plane anisotropy. In an embodiment, the magnetic free layer 40 may be, for example, CoFeB.

In the embodiment illustrated in FIG. 1, the SOT layer 100 is a conventional SOT material. The term “conventional SOT material” defines a SOT material in which the spin-orbit torque is only along the y-axis. While the SOT layer 100 is illustrated as a single layer in FIG. 1, this is only an example and, in some embodiments, a plurality of layers may be provided. In other words, the SOT layer 100 may be formed of a plurality of layers.

In the y-type two terminal SOT MRAM device 1, a switching current Iwrite flows along the x-axis. The y-axis is into and out of the page. Thus, in the y-type two terminal SOT MRAM device 1, when the switching current Iwrite is applied to the SOT layer 100, the spin polarization direction for the spin-orbit torque (SOT) and the spin-transfer torque (STT) are both along the y-axis. In other words, for the y-type two terminal SOT MRAM device 1 using conventional SOT materials, the STT follows the easy axis anisotropy of the MTJ 50, and the SOT in the SOT layer 100 is always along the y-axis direction, as illustrated in FIG. 2.

Compared to related art STT MRAM technology, the y-type two terminal SOT MRAM device 1 introduces the conventional SOT material adjacent to the magnetic free layer 40 of the MTJ 50 to achieve field-free switching to improve the switching speed and reduce the write current of the y-type two terminal SOT MRAM device 1, while maintaining a high-density bit cell layout. The orientation of the magnetic free layer 40 may be switched field-free between a parallel state (P) and an antiparallel state (AP) as illustrated in FIG. 3A by injecting a current through the MTJ 50 of the y-type two terminal SOT MRAM device 1. Here, the parallel state (P) denotes 0 degrees of angular separation between the magnetic orientation of the free layer and the fixed layer and the antiparallel state (AP) denotes 180 degrees of angular separation between the magnetic orientation of the free layer and the fixed layer, as illustrated in FIG. 3A. As shown in FIG. 3A, the parallel state provides a parallel resistance RP that is lower than an antiparallel resistance RAP in the antiparallel state. For digital storage, 0 degrees for the parallel state (P) and 180 degrees for the antiparallel state (AP) provides a maximum difference of resistance. Here, the tunneling magnetoresistive ratio (TMR)=(RAP−RP)/RP*100%. The direction of the current determines the final state (e.g., parallel state (P) or antiparallel state (AP)) of the y-type two terminal SOT MRAM device 1.

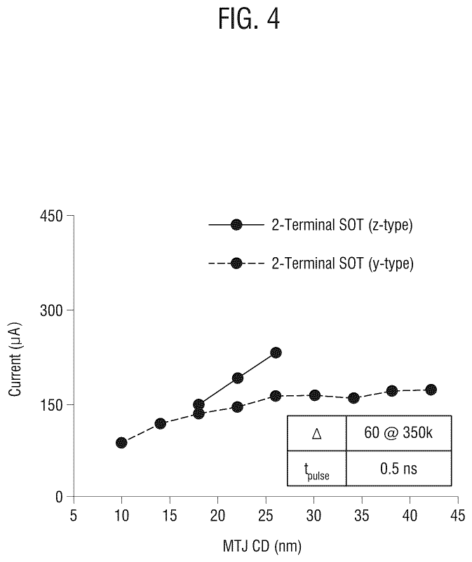

FIG. 4 illustrates switching current verses MTJ critical dimension (CD) for the y-type two terminal SOT MRAM device with conventional SOT material, according to some embodiments.

As illustrated in FIG. 4, the y-type two terminal SOT MRAM device with the conventional SOT material provides better switching current than a z-type two terminal SOT MRAM device.

In the y-type two terminal SOT MRAM device with the conventional SOT material, field-free switching occurs with MTJ CD of about 10 nm to about 43 nm with switching current of about 80 μA to about 160 μA. Thus, the y-type two terminal SOT MRAM device with the conventional SOT material uses a lower amount of switching current (e.g., an ISW from about 80 μA to about 160 μA) as compared to a z-type two terminal SOT MRAM device with the conventional SOT material.

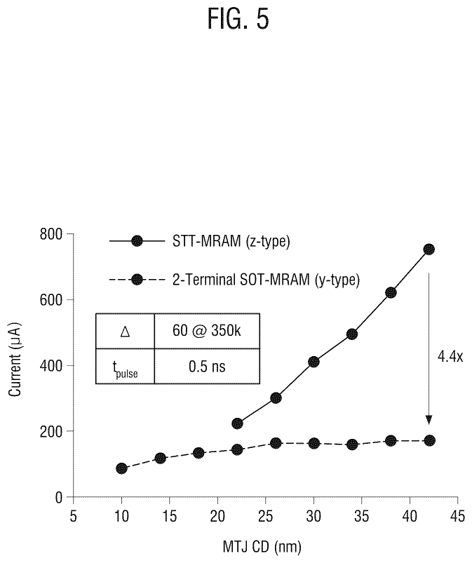

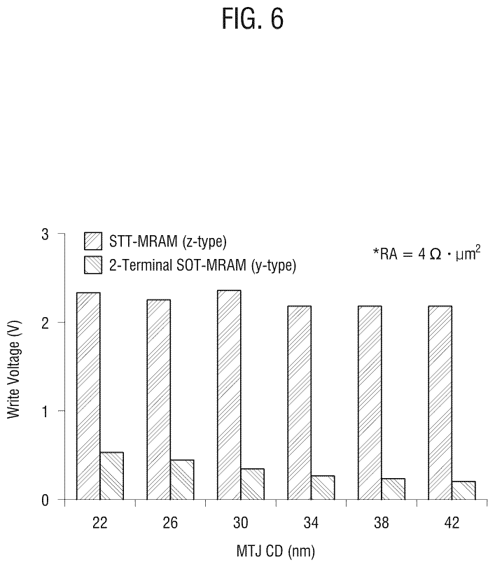

FIG. 5 illustrates switching current verses MTJ critical dimension (CD) for the y-type two terminal SOT MRAM device with conventional SOT material, according to some embodiments, as compared with an STT MRAM (z-type) device. FIG. 6 illustrates write voltage versus the MTJ CD for the y-type two terminal SOT MRAM device with conventional SOT material, according to some embodiments, as compared with an STT MRAM (z-type) device.

As shown in FIG. 5, the y-type two terminal SOT MRAM device with conventional SOT material requires 4.4× less switching current ISW than the STT MRAM device. In the y-type two terminal SOT MRAM device with conventional SOT material, for a current pulse time tpulse of 0.5 ns with a Δ of 60 @ 350k, an MTJ CD of about 10 nm to about 43 nm requires a switching current of about 80 μA to about 160 μA. By contrast, the STT MRAM for a MTJ CD of about 22 nm to about 43 nm requires a switching current of about 210 μA to about 750 μA, which is much higher.

Additionally, the write voltage for the y-type two terminal SOT MRAM device with conventional SOT material is also lower than that of the STT MRAM (z-type) device. In the y-type two terminal SOT MRAM device with conventional SOT material, an RA of 4Ω/μm2, a MTJ CD of about 22 nm to about 42 nm requires a voltage of about 0.5 v to about 0.25 v. By contrast, in the STT MRAM (z-type) with an RA of 4 Ω/μm2, a MTJ CD of about 22 nm to about 42 nm requires a voltage of about 2.3 v.

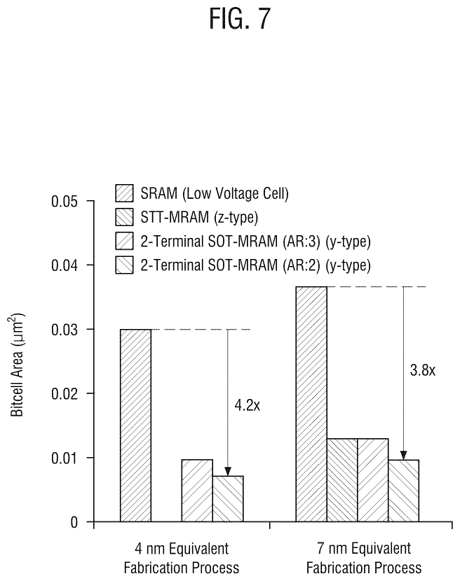

FIG. 7 illustrates a bit cell area density of a y-type two terminal SOT MRAM device with conventional SOT material, according to some embodiments, in two fabrication processes as compared with an STT MRAM (z-type) device and a SRAM device.

The y-type two terminal SOT MRAM device with conventional SOT material allows for about a 4× denser device as compared to an SRAM device. FIG. 7 shows bit cell area in μm2 for the various devices in a 4 nm mode equivalent fabrication process having a contacted gate pitch (CGP) of 50 nm, a minimum metal pitch (MMP) of 30 nm, a SRAM cell size (μm2) of 0.03, a MTJ CD (=0.5* MMP) of 16 nm, and a MTJ switching speed target of 0.5 ns, and a 7 nm mode equivalent fabrication process having a contacted gate pitch (CGP) of 54 nm, a minimum metal pitch (MMP) of 40 nm, a SRAM cell size (μm2) of 0.0367, a MTJ CD (−0.5 * MMP) of 20 nm, and a MTJ switching speed target of 0.5 ns. As shown in FIG. 7, depending on the process technology used, the bit cell area may be reduced by about 3.8× to about 4.2× that of a comparable SRAM device. For example, for the 4 nm mode equivalent fabrication process, the bit cell area may decrease from 0.03 μm2 to less than 0.01 μm2.

A z-type two terminal SOT MRAM device has been demonstrated experimentally in the related art. For the z-type two terminal SOT MRAM device with conventional SOT material, the field-free switching window is very limited. For example, in the experimentally demonstrated z-type two terminal SOT MRAM device with its specific SOT material and geometry, field-free switching is only available for MTJ CDs of about 18-26 nm for a switching current of about 150 μA to about 225 μA. Above that MTJ CD range, the z-type two terminal SOT MRAM device with conventional SOT material is non-deterministic without an external magnetic field or bias field being applied to assist to achieve deterministic operation. Below that MTJ CD range the perpendicular magnetic anisotropy becomes insufficient and it is difficult to maintain the thermal stability factor of the z-type two terminal SOT MRAM device. That is, for large MTJ CDs, the z-type two terminal SOT MRAM device switching characteristic becomes non-deterministic without an external magnetic field or bias fieldbeing applied to assist to achieve deterministic operation. By contrast, when the MTJ CD becomes small, it is difficult to maintain the thermal stability factor of the z-type two terminal SOT MRAM device with conventional SOT material.

In the related art, various terms are used for the external magnetic field-“dipole field”, “external magnetic field”, “bias magnetic field”, etc. The external magnetic field is typically generated by an additional layer, variously called “an in-plane magnetized magnetic layer”, an “in-plane magnetized bias magnetic field providing layer”, etc., and requires the additional magnetic layer and/or an additional current to be applied to the additional magnetic layer in order to generate the assisting external magnetic field necessary to achieve deterministic switching. As another example, deterministic operation and state switching may be provided by introducing a canting axis via the geometry of the z-type two terminal SOT MRAM device having the conventional SOT material. In these cases, the high switching current combined with the additional current needed to generate the assisting external magnetic field or the complex fabrication method needed to introduce the canting axis into the device geometry makes the z-type two terminal SOT MRAM devices using conventional SOT materials impractical for high integration memories in which lower current, higher densities, and scalable fabrication are advantageous.

However, the present inventors have found that by introducing unconventional SOT materials into the z-type two terminal SOT MRAM device, the z-type two terminal SOT MRAM device unexpectedly achieves field-free deterministic switching with a wider field-free switching window and a reduced switching current. As used in this specification, the term “field-free switching” is defined as a deterministic operation that achieves state switching without needing the assistance of an external magnetic field or bias field. Moreover, that a “device achieves field-free switching” is defined as a SOT MRAM device that is able to achieve deterministic operation and state switching on its own without needing the assistance of an external magnetic field and without the need for an additional layer or an additional current necessary to generate the assisting external magnetic field.

By introducing unconventional SOT materials into the z-type two terminal SOT MRAM device, the z-type two terminal SOT MRAM device with the unconventional SOT material unexpectedly achieves greater than a 2× reduction in switching current and about a 4× increase in switching speed as compared with a z-type two terminal SOT MRAM with conventional SOT material.

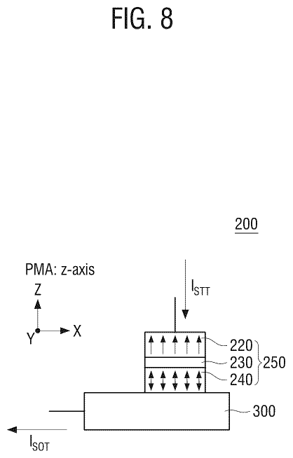

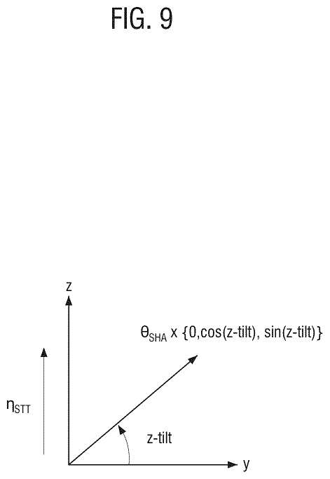

FIG. 8 illustrates an example of a z-type two terminal SOT MRAM device with unconventional SOT material, according to some embodiments. FIG. 9 illustrates the spin-orbit torque (SOT) and a tilt angle in an unconventional SOT material and the spin-transfer torque (STT), according to some embodiments.

In FIG. 8, a z-type two terminal SOT MRAM device 200 may include a magnetic tunnel junction (MTJ) 250 and a spin-orbit torque (SOT) layer 300. The MTJ 250 includes a fixed magnetization layer 220, a tunnel barrier layer 230, and a magnetic free layer 240 in order from top to bottom in FIG. 8, such that an upper surface of the SOT layer 300 contacts the magnetic free layer 240. In an embodiment, a first terminal may be connected to the fixed magnetization layer 220 of the MTJ 50, and a second terminal may be connected to the SOT layer 300. The MTJ 250 has easy axis anisotropy along the z-axis (out-of-plane) direction, as described above. In other words, the MTJ 250 may be an out-of-plane magnetic tunnel junction, also known as a magnetic tunnel junction with an out-of-plane or perpendicular magnetic anisotropy (PMA). In an embodiment, the magnetic free layer 240 may be, for example, CoFeB.

In the embodiment illustrated in FIG. 8, the SOT layer 300 is an unconventional SOT material. The term “unconventional SOT material” defines a SOT material in which the spin-orbit torque has components along both the y-axis and another axis. The “unconventional SOT material” refers to low-symmetry SOT materials where spin polarization, spin current, and charge current are not enforced to be orthogonal. In contrast to the conventional SOT material in which the spin-orbit torque is only along the y-axis, in the unconventional SOT material, the spin-orbit torque tilts away from the y-axis toward either the x-axis or the z-axis such that the spin-orbit torque is in the y-axis and in either the x-axis or the z-axis. While the SOT layer 300 is illustrated as a single layer in FIG. 8, this is only an example and, in some embodiments, a plurality of layers may be provided. In other words, the SOT layer 300 may be formed of a plurality of layers.

SOT materials with unconventional spin polarization in the in-plane x-type orientation and/or the out-of-plane z-type orientation are an emerging class of SOT materials that enable field-free switching and further improve the energy efficiency of the SOT MRAM device. While the origin of unconventional spin polarization is still being researched, several mechanisms with accompanying experimental demonstrations and theoretical calculations have been performed. For instance, out-of-plane unconventional spin polarization in MnPd3 have been demonstrated, where density functional theory calculations show that the unconventional spin polarization resulted from low crystal symmetry of (114)-oriented MnPd3 films. In addition to MnPd3, unconventional spin polarization has been discovered in a wide range of SOT materials, including Mn3Sn, WTe2, IrMn, RuO2, L10-FePt/Cu/Py, CuPt, etc.

In the z-type two terminal SOT MRAM device 200, a switching current Isw flows along the x-axis, and the y-axis is into and out of the page. In the z-type two terminal SOT MRAM device 200, when the switching current Isw is applied to the SOT layer 300, the spin polarization direction for the spin-orbit torque (SOT) is along the y-axis and another axis (x-axis or z-axis) and the spin-transfer torque (STT) is along the z-axis. In other words, for unconventional SOT materials, there is a tilt angle away from the y-axis toward either the x-axis or the z-axis. A z-tilt angle is illustrated in the example shown in FIG. 9.

Using unconventional SOT materials further reduces the switching current and expands the field-free switching window in the z-type two terminal SOT MRAM device. As illustrated in FIG. 9, the net effect of the tilt angle is that the tilt angle allows the spin-orbit torque (SOT) to contribute more towards the z-axis direction in the z-type two terminal SOT MRAM device, where the z-axis direction is the easy axis which makes switching more efficient. In FIG. 9, OSHA indicates a spin Hall angle.

In a conventional SOT material, only the spin-transfer torque (STT) contributes to the z-axis spin direction. By contrast, in the unconventional SOT material, both the spin-orbit torque (SOT) and the spin-transfer torque (STT) contribute to the z-axis spin direction.

The inventors have found unexpectedly that the unconventional SOT material itself can change the tilt angle due to the crystalline structure of the SOT material. Thus, changing the from the conventional SOT material to the unconventional SOT material introduces the tilt axis.

More specifically, the inventors found that the ratio of the current in-plane in the SOT material (JSOT) to the current perpendicular to the plane of the SOT material (JSTT) determines the switching behavior in the z-type two terminal SOT MRAM device. Here, a high JSOT/JSTT ratio indicates that the spin contribution from the SOT material dominates, whereas a low JSOT/JSTT ratio indicates that the spin contribution from the STT dominates. This ratio explains why an external magnetic field assist is required at large tunnel junction dimensions.

The JSOT/JSTT ratio depends on device geometry. With reference to FIG. 8, Kirchhoff's Current Law requires that ISOT=ISTT.

Here,

$$\frac{{J}_{SOT}}{{J}_{STT}} = \frac{{A}_{MTJ}}{{A}_{SOT}} ∝ \frac{{MTJ}_{CD}}{{t}_{SOT}} ,$$

assuming that W_{SOT}˜MTJ_{CD}., where MTJCD is the critical dimension of the MTJ.

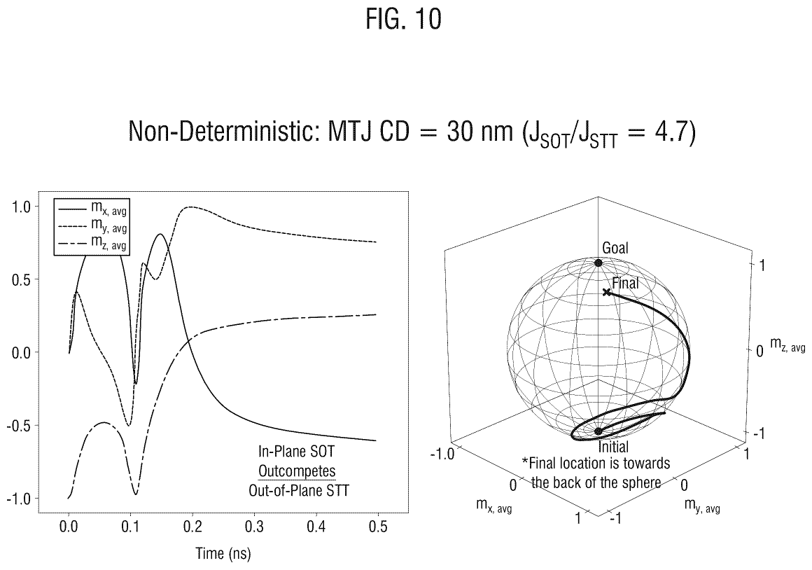

FIG. 10 illustrates a simulation of non-deterministic operation in a z-type two terminal SOT MRAM device with an MTJ critical dimension (CD) of 30 nm and a conventional SOT material. As shown in FIG. 10, the JSOT/JSTT ratio is 4.7. The left hand graph in FIG.

10 illustrates magnetization mx, my, and mz in the x-axis, y-axis and z-axis directions, respectively over time t in ns. The right hand graph illustrates the initial state and final state of the magnetism components in a coordinate system in three dimensions. As illustrated in the left hand graph, a steady state switching current was applied starting at time t=0 and maintained for 0.5 ns, at which point the switching current was turned off. In this case, as shown in the left hand graph, the in-plane spin-orbit torque (SOT) outcompetes the out-of-plane spin-transfer torque (STT). Thus, as illustrated in the right hand graph, the initial location starts at coordinate (0, 0, 0) at the point t=0, and the final location at time t=0.5 ns when the switching current is turned off is not located on the z-axis but rather the final location is located towards the middle and back of the sphere. Thus, it is not clear whether the state of the material will fall back to the initial location, resulting in non-deterministic operation.

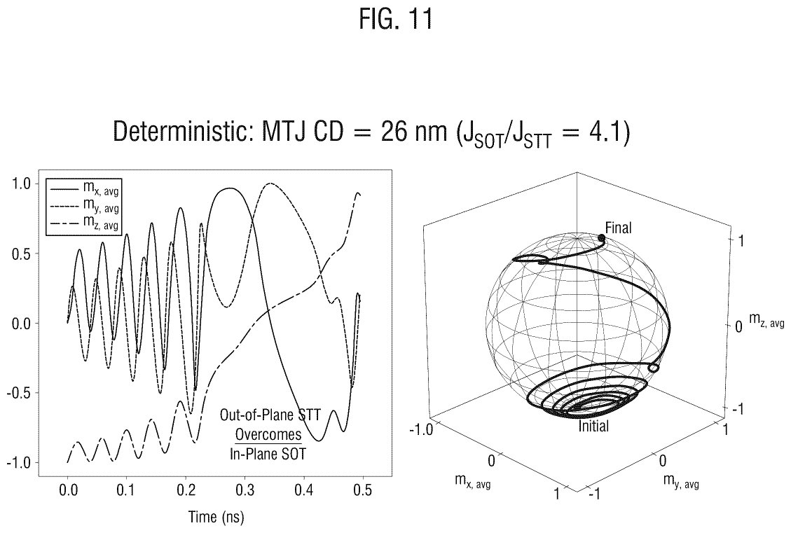

FIG. 11 illustrates a simulation of deterministic field-free switching in a z-type two terminal SOT MRAM device with an MTJ critical dimension (CD) of 26 nm and an unconventional SOT material. As shown in FIG. 11, the JSOT/JSTT ratio is 4.1. Similar to FIG. 10, the left hand graph in FIG. 11 illustrates magnetization mx, my, and mz in the x-axis, y-axis and z-axis directions, respectively over time t in ns. The right hand graph illustrates the initial state and final state of the magnetism components in a coordinate system in three dimensions. As illustrated in the left hand graph, a steady state switching current was applied starting at time t=0 and maintained for 0.5 ns, at which point the switching current was turned off. In this case, in contrast to FIG. 10, as shown in the left hand graph, the out-of-plane spin-transfer torque (SOT) overcomes the in-plane spin-orbit torque (SOT) such that the magnetic free layer 240 becomes deterministic. Thus, as illustrated in the right hand graph, the initial location starts at coordinate (0, 0, 0) at the point t=0, and the final location at time t=0.5 ns when the switching current is turned off is located close to the z-axis. Thus, as time progresses past t=0.5 ns, the state of the material will not fall back to the initial state but will end up at coordinate (0, 0, 1), resulting in non-deterministic operation. As noted above, the direction of the switching current determines the final state (i.e., whether the final state is parallel (P) or antiparallel (AP)) of the z-type two terminal SOT MRAM device with unconventional SOT material.

Comparing the simulations of FIG. 10 and FIG. 11, non-deterministic operation may be compared with deterministic switching. For the deterministic field-free switching, the MTJ critical dimension (CD) is 26 nm and the JSOT/JSTT ratio is 4.1. Thus, field-free switching is naturally enabled as the MTJ CD decreases.

Therefore, when the device is large, the external magnetic field assistance is needed to overcome the in-plane SOT. However, unexpectedly, the inventors found that, as the dimensions of the z-type two terminal SOT MRAM device decrease (i.e., as MTJ CD decreases), the z-type two terminal SOT MRAM device is able to switch field-free (i.e., without the external magnetic field assist).

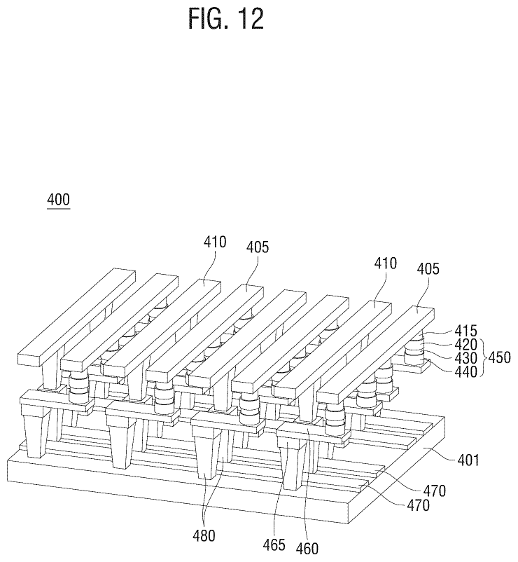

FIG. 12 illustrates an example bit cell layout of a z-type two terminal SOT MRAM device with SOT material below the magnetic tunnel junction (MTJ), according to some embodiments.

As shown in FIG. 12, a bit cell layout 400 of the z-type two terminal SOT MRAM device may include a substrate 401, bit lines 405, source lines 410, word lines 470, a magnetic tunnel junction (MTJ) 450, a SOT layer 460, metal layers 415 and 465, and vias 480. The metal layer 415 may be a contact for connecting the bit lines 405 to the MTJ 450, and the metal layer 465 may be a contact for connecting the vias 480 to the SOT layer 460.

The MTJ 450 may be top pinned and may include a fixed magnetic layer 420, a tunnel barrier layer 430, and a magnetic free layer 440. The MTJ 450 may have easy axis anisotropy in the z-axis direction (perpendicular magnetic anisotropy (PMA). In an embodiment, the SOT layer 460 may be provided below the MTJ 450 and an upper surface of the SOT layer 460 may contact the magnetic free layer 440. In an embodiment, the SOT layer 460 may be an unconventional SOT material as described above. In an embodiment, the bit cell layout 400 may be an example bit cell layout of the z-type two terminal SOT MRAM device 200 described above with respect to FIG. 8.

In FIG. 12, a number of metal layers may be about two layers. A minimum bit cell size may be 12F2.

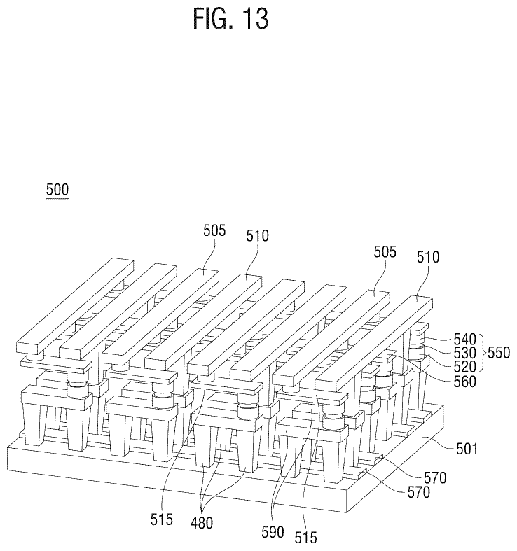

FIG. 13 illustrates an example of a bit cell layout of a z-type two terminal SOT MRAM with SOT material above the MTJ, according to some embodiments.

As shown in FIG. 13, a bit cell layout 500 of the z-type two terminal SOT MRAM device may include a substrate 501, bit lines 505, source lines 510, word lines 570, a magnetic tunnel junction (MTJ) 550, a SOT layer 560, metal layers 515 and 590, and vias 580. The metal layer 515 may be a contact for connecting the bit lines 505 to the SOT layer 560, and the metal layer 590 may be a contact for connecting vias 580 to the MTJ 550. The MTJ 550 may be bottom pinned and may include a fixed magnetic layer 520, a tunnel barrier layer 530, and a magnetic free layer 540. The MTJ 550 may have easy axis anisotropy in the z-axis direction (perpendicular magnetic anisotropy (PMA). The SOT layer 560 may be an unconventional SOT material as described above. In an embodiment, the SOT layer 560 may be provided above the MTJ 550 and a lower surface of the SOT layer 560 may contact the magnetic free layer 440. In an embodiment, the bit cell layout 500 may be an example bit cell layout of the z-type two terminal SOT MRAM device 200 described above with respect to FIG. 8.

In FIG. 13, a number of metal layers may be about three layers. A minimum bit cell size may be 12F2 for a MTJ AR=2. A minimum bit cell size may be 16F2 for an MTJ AR=3 (see FIG. 7).

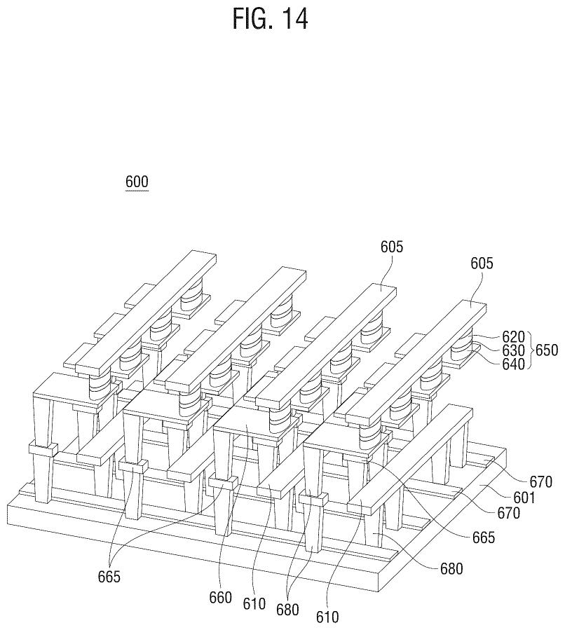

FIG. 14 illustrates an example of a bit cell layout of a y-type two terminal SOT MRAM with SOT material below the MTJ, according to some embodiments.

As shown in FIG. 14, a bit cell layout 600 of the y-type two terminal SOT MRAM device may include a substrate 601, bit lines 605, source lines 610, word lines 670, a magnetic tunnel junction (MTJ) 650, a SOT layer 660, a metal layer 665, and vias 480. The metal layer 665 may be a contact for connecting the vias 480 to the SOT layer 660.

The MTJ 650 may be top pinned and may include a fixed magnetic layer 620, a tunnel barrier layer 630, and a magnetic free layer 640. The MTJ 650 may have easy axis anisotropy in the y-axis direction (in-plane magnetic anisotropy (IMA). In an embodiment, the SOT layer 660 may be provided below the MTJ 650 and an upper surface of the SOT layer 660 may contact the magnetic free layer 640. In an embodiment, the SOT layer 660 may be an conventional SOT material as described above. However, embodiments are not limited thereto and, in an embodiment, the SOT layer 660 may be an unconventional SOT material as described above. In an embodiment, the bit cell layout 600 may be an example bit cell layout of the y-type two terminal SOT MRAM device 1 described above with respect to FIG. 1.

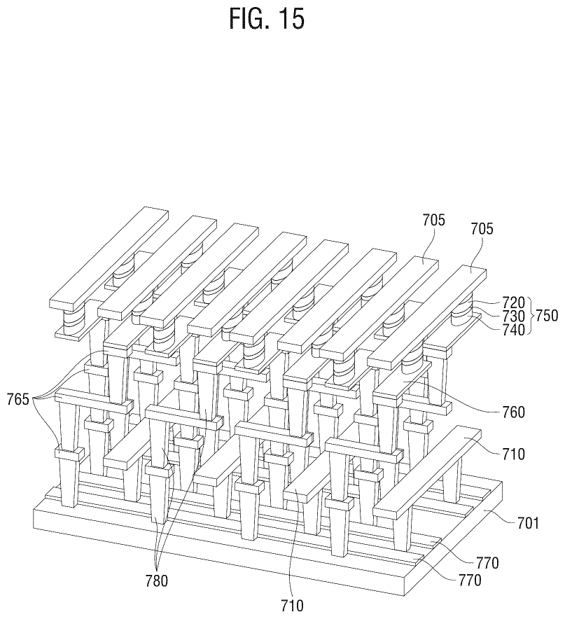

In FIG. 14, a number of metal layers may be about three layers. A minimum bit cell size may be 12F2 for a MTJ AR=2. A minimum bit cell size may be 16F2 for an MTJ AR=3 (see FIG. 7).FIG. 15 illustrates an example of a bit cell layout of an x-type two terminal SOT MRAM with SOT material below the MTJ, according to some embodiments.

As shown in FIG. 15, a bit cell layout 700 of the x-type two terminal SOT MRAM device may include a substrate 701, bit lines 705, source lines 710, word lines 770, a magnetic tunnel junction (MTJ) 750, a SOT layer 760, a metal layers 765, and vias 780. The metal layers 765 may be a contact for connecting the vias 780 to the SOT layer 760.

The MTJ 750 may be top pinned and may include a fixed magnetic layer 720, a tunnel barrier layer 730, and a magnetic free layer 740. The MTJ 750 may have easy axis anisotropy in the x-axis direction (in-plane magnetic anisotropy (IMA). In an embodiment, the SOT layer 760 may be provided below the MTJ 750 and an upper surface of the SOT layer 760 may contact the magnetic free layer 740. In an embodiment, the SOT layer 760 may be an conventional SOT material as described above. However, embodiments are not limited thereto and, in an embodiment, the SOT layer 760 may be an unconventional SOT material as described above. In an embodiment, the bit cell layout 700 may be an example bit cell layout similar to the bit cell layout of the y-type two terminal SOT MRAM device 1 described above with respect to FIG. 1, except that the in-plane magnetic anisotropy is in the x-axis direction.

In FIG. 15, a number of metal layers may be about two to four layers. A minimum bit cell size may be 12F2 for a MTJ AR=2. A minimum bit cell size may be 12F2 for an MTJ AR=3 (see FIG. 7).

The z-type, y-type, and x-type two terminal SOT MRAM devices leverages the synergy between spin-transfer torque (STT) and spin-orbit torque (SOT) to enable field-free switching in a high-density, one transistor, one resistor per cell (1TIR) bit cell layout, as described with respect to the examples illustrated in FIGS. 12-15, where each bit cell contains one transistor and one resistive storage element. Compared to related art STT MRAM technology, each of the z-type, y-type, and x-type two terminal SOT MRAM devices illustrated in FIGS. 12-15 introduces a SOT material adjacent to the free layer of the magnetic tunnel junction (MTJ). The adjacent SOT material improves the switching speed and reduces the write current of the device, while maintaining a high-density 1TIR bit cell layout.

While the examples in FIGS. 14-15 illustrate the y-type and x-type two terminal SOT MRAM devices with the SOT material integrated below the MTJs 660 and 760, respectively. According to some embodiments, each of the y-type and x-type two terminal SOT MRAM devices may include the SOT material integrated above the MTJ with appropriate modification in a similar manner as in the example of the bit cell layout for the z-type two terminal SOT MRAM device illustrated with respect to FIG. 13.

In an embodiment, the SOT material may be connected in series with the MTJ. In an embodiment, an orientation of the free layer may be switched between a parallel (P) state and an antiparallel (AP) state by injecting a current through the bitline 405, 505, 605, or 705 into a top electrode of the two terminal SOT MRAM device. The current may be, for example, a charge current. In an embodiment, as discussed above, the direction of the current determines the final state (i.e., parallel (P) or antiparallel (AP)) of the two terminal SOT MRAM device.

When the charge current is injected into the top electrode of the two terminal SOT MRAM device through the bitline 405, 505, 605, or 705, both spin-orbit torque (SOT) and spin-transfer torque (STT) are generated. As discussed above, the spins generated by the SOT are polarized in the in-plane y-orientation in a conventional SOT material. The spins generated by the STT are polarized coaxially to the easy-axis anisotropy of the two terminal SOT MRAM device. For example, when the x-direction denotes a direction of the current flow through the SOT material, the z-direction denotes a direction of current flow through the MTJ.

In z-type two terminal SOT MRAM devices with the unconventional SOT material (i.e., with perpendicular magnetic anisotropy (PMA)), the synergy between the spins generated by the SOT and the spins generated by the STT has several key benefits.

For example, a spin polarization angle of the spins generated by the SOT is nominally orthogonal to the anisotropy of the two terminal SOT MRAM device such that a maximum spin-orbit torque (SOT) is applied to the free layer initially when current is injected into the two terminal SOT MRAM device. As a result, switching can begin immediately. In contrast, a spin polarization angle of the spins generated by the STT is coaxial to the easy-axis anisotropy of the two terminal SOT MRAM device. Thus, the initial spin-transfer torque (STT) is close to zero such that a thermally-activated incubation time is required to establish an initial angle before switching can begin. For this reason, the switching latency of the two terminal SOT MRAM device is much improved (i.e., the switching occurs much faster) as compared with the switching latency of a related art spin-transfer torque (STT) MRAM device. For example, the switching speed in the two terminal SOT MRAM device may be about four times (4x) faster than the switching speed in the related art spin-transfer torque (STT) MRAM device. This faster speed is because thermal energy is not required to initiate switching in the two terminal SOT MRAM device. This benefit is more pronounced at lower temperature, because less thermal energy is available to establish an initial angle in the related art spin-transfer torque (STT) MRAM device. In situations in which the related art spin-transfer torque (STT) MRAM device is subject to high energy radiation, such as in space related applications, the increased thermal energy from the high energy radiation may cause errors in switching. By contrast, the two terminal SOT MRAM device is naturally immune to such soft-errors induced by high energy radiation, because data is stored magnetically in the free layer of the MTJ. For this reason, the two terminal SOT MRAM device is particularly suited to aerospace and space applications in which radiation hardness and ultralow temperature operation is naturally enabled by the synergy between the spins generated by the SOT and the spins generated by the STT.

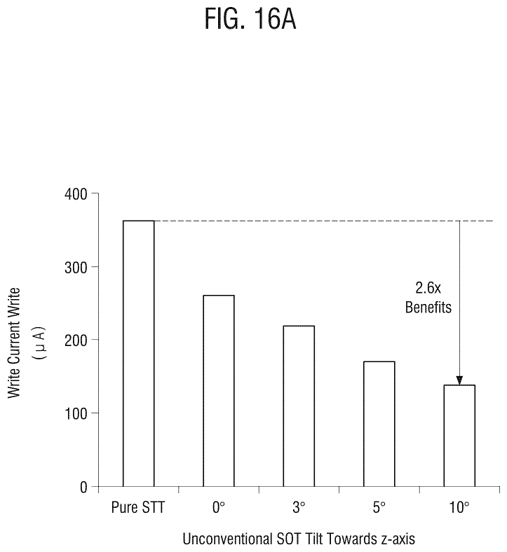

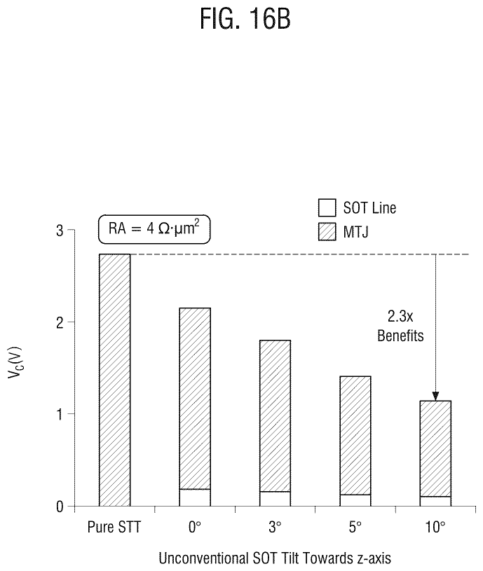

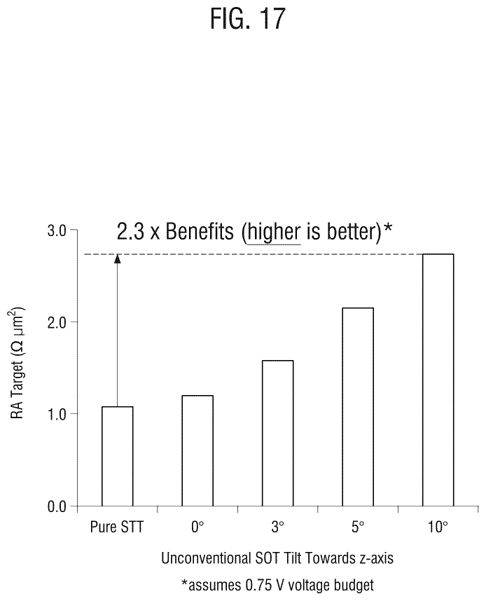

FIG. 16A illustrates switching current in the z-type two terminal SOT MRAM for various unconventional SOT tilt angles according to some embodiments, with the switching current of pure STT MRAM (z-type) shown as a reference. FIG. 16B illustrates charge voltage in the z-type two terminal SOT MRAM for various unconventional SOT tilt angles according to some embodiments, with the write voltage of pure STT MRAM (z-type) shown as a reference. FIG. 17 illustrates a resistance-area (RA) target in the z-type two terminal SOT MRAM for various unconventional SOT tilt angles according to some embodiments, with the RA target of pure STT MRAM (z-type) shown as a reference.

In two terminal SOT MRAM devices with conventional SOT materials, the x-spin to y-spin ratio or the z-spin to y-spin ratio is primarily determined by device geometry. By introducing SOT materials with unconventional spin polarizations, the x-spin to y-spin ratio or the z-spin to y-spin ratio may be enhanced to further improve the switching performance.

As illustrated in FIG. 16A, according to various embodiments, an unconventional tilt angle of 5° towards the z-axis reduces switching current by more than two times (2×) as compared to the switching current in the related art STT MRAM (z-type). For example, the switching current of the related art STT MRAM (z-type) is about 370 μA, whereas the switching current for the z-type two terminal SOT MRAM with unconventional SOT tilt angle of 5° towards the z-axis is about 180 μA. For example, for an unconventional tilt angle to 10°, the reduction of the switching current is even higher, from about 370 μA to about 150 μA. The unconventional tilt angle is defined to be an angular separation between a spin-orbit torque (SOT) spin polarization vector and the y-axis. A higher unconventional tilt angle corresponds to a higher x-spin to y-spin ratio or z-spin to y-spin ratio. Such a dramatic decrease in the switching current may be attributed to the z-spin current density generated in the SOT material. The z-spin current density reduces the spin-transfer torque (STT) current density and overall write current required for switching.

As illustrated in FIG. 16B, the z-type two terminal SOT MRAM with unconventional SOT tilt angles provides a 2.3× decrease in write voltage Vc (V) as compared to the pure STT MRAM (z-type) device for an RA of 4 Ω·um2. Here, the contribution of the voltage from the SOT line is small compared to the contribution of the MTJ. For example, the pure STT MRAM (z-type) device has a wrie voltage of about 2.8 V, whereas the write voltage of the z-type two terminal SOT MRAM with unconventional SOT tilt angle of 10° towards the z-axis is about 1.25 V.

The reduction in the spin-transfer torque (STT) current density increases an available areal resistance (RA) budget by more than two times (2×) as compared to a pure STT MRAM (z-type) device, as illustrated in FIG. 17. For example, assuming a 0.75 V voltage budget, the RA target of the related art STT MRAM (z-type) is about 1.1 Ω·um2, whereas the RA target for the z-type two terminal SOT MRAM with unconventional SOT tilt angle of 5° towards the z-axis is about 2.0 Ω·um2. Similar to the switching current performance, for an unconventional tilt angle to 10°, the increase of the RA target even higher, from about 1.1 Ω·um2 to about 2.6 Ω·um2. This increased RA budget improves the manufacturability and scalability of the magnetic tunnel junction (MTJ) as compared with the related art STT MRAM technology. FIGS. 16 and 17 illustrate a trend in which greater benefits are enabled by increasing the unconventional SOT tilt angle towards the z-axis.

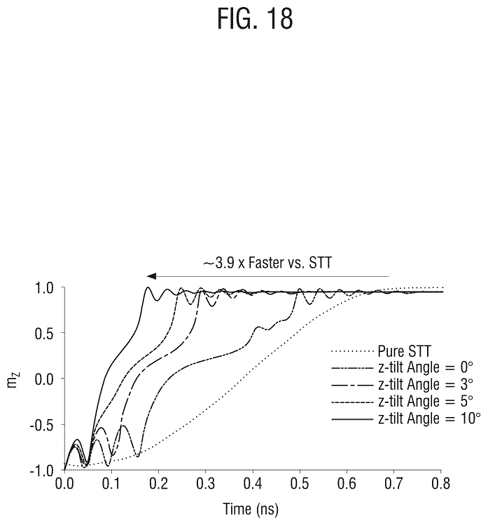

FIG. 18 illustrates magnetization trajectory along the z-axis as a function of time for a z-type two terminal SOT MRAM with unconventional SOT material, according to some embodiments.

According to various embodiments, a unconventional tilt angle of 10° reduces the switching latency by about four times (4×) compared to the switching latency of the related art STT MRAM technology. For example, for the related art STT MRAM (z-type) to reach a magnetization of 1.0 for switching takes about 0.65 ns. By contrast, the z-type two terminal SOT MRAM with unconventional SOT material having a tilt angle of 10° reaches a magnetization for 1.0 for switching in about 0.17 ns.

The above embodiments are illustrated with respect to perpendicularly polarized z-type magnetic tunnel junctions (MTJs). According to various embodiments, the unconventional tilt angle may also be applied to in-plane polarized magnetic tunnel junctions (MTJs) (e.g., in-plane polarized x-type MTJs or in-plane polarized y-type MTJs).

Such dramatic improvements in switching speed and reduction in write current generated by two terminal SOT MRAM including unconventional SOT materials demonstrates great promise as a next-generation nonvolatile memory technology.

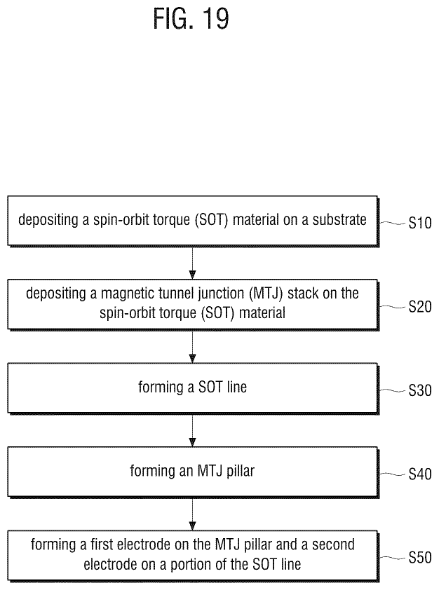

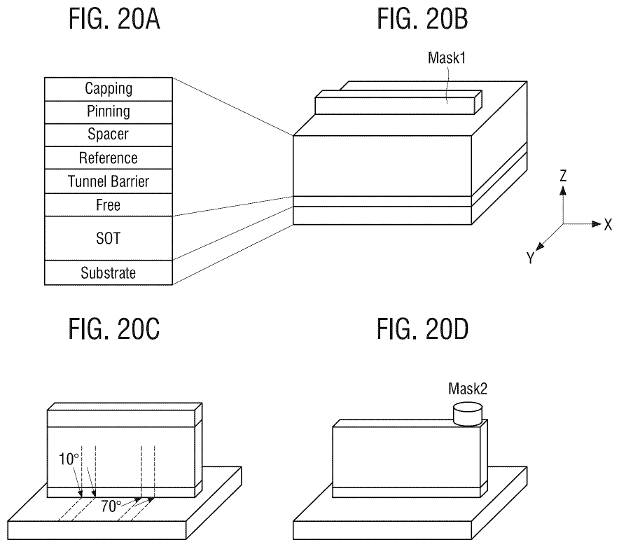

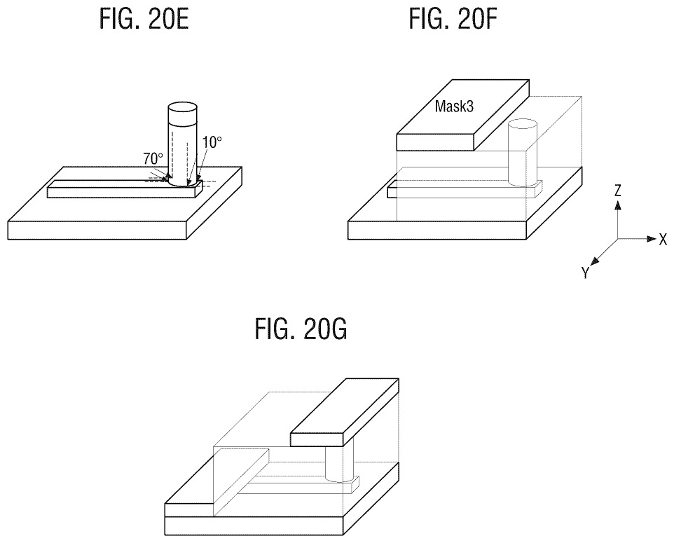

FIG. 19 illustrates a flowchart of operations of a method of manufacturing a z-type two terminal SOT MRAM device having SOT material below the MTJ and perpendicular magnetic anisotropy, according to some embodiments. FIGS. 20A to 20G illustrate the method of manufacturing the z-type two terminal SOT MRAM device having SOT material below the MTJ and perpendicular magnetic anisotropy, according to some embodiments.

According to an embodiment, the z-type two terminal SOT MRAM device with perpendicular magnetic anisotropy may be fabricated by a fabrication process illustrated in FIGS. 20A to 20G. It is noted that a similar fabrication process may be used for MTJs with in-plane magnetic anisotropy. However, embodiments are not limited to the fabrication process illustrated in FIGS. 20A to 20G and, according to some embodiments, other fabrication processes may be used to fabricate the two terminal SOT MRAM.

In the description that follows, the fabrication process illustrated in FIGS. 20A to 20G will be explained with respect to fabricating the z-type two terminal SOT MRAM device with the SOT line integrated below the MTJ as illustrated in FIG. 12, and with reference to the operations illustrated in FIG. 19.

The fabrication process begins with depositing a spin-orbit torque (SOT) material on a substrate (S10). In some embodiments, the SOT material may be an unconventional SOT material. In some embodiments, the SOT material may be a conventional SOT material. In some embodiments, the SOT material may comprise a plurality of layers. A magnetic tunnel junction (MTJ) stack may then be depositing on the SOT material (S20). For example, as illustrated in FIG. 20A, in some embodiments, the MTJ stack may include a free layer, a tunnel barrier layer, a reference layer, a spacer layer, a pinning layer, and a capping layer, in order, deposited on the SOT layer. However, this is only an example and, in some embodiments, the number of layers may be changed. In some embodiments, the MTJ stack may be a perpendicular MTJ stack. In some embodiments, the MTJ stack may be an in-plane MTJ stack. In some embodiments, for example, a low areal-resistance (RA) MTJ stack with SOT such as SOT thin film, Layer/CoFe (1)/MgO(1.2)/CoFeB(1.3)/Ta(0.4)/Co(0.4)/Pd(0.6)/Co(0.4)/Ru(0.85)/Co(0.4)/[P d(0.6)/Co(0.3)]3/Ru(1.5) with units in nm may be provided. According to an embodiment, the MTJ stack may be deposited via magnetron sputtering on a surface-passivated CMOS die and vacuum annealed at 200° C. for 1 hour. A SOT line may be formed (S30). For example, in some embodiments, a first mask (Mask 1) may be provided on the MTJ stack using negative-tone resist, as illustrated in FIG. 19B. As illustrated in FIG. 19C, the SOT line may be patterned with E-beam lithography (EBL) based on the first mask by two-step ion-beam etching with in-situ passivation via Al2O3 sputtering and resist liftoff. The etching of the SOT line may stop at the passivation substrate and the surface of the SOT layer, respectively, using accurate time control or endpoint detection via secondary ion mass spectrometry. In an embodiment, a minimum width of the SOT line may be about 30 nm or below (e.g., about 5 nm to about 30 nm), and a length of the SOT line may vary according to the embodiment. A MTJ pillar may be formed (S40). For example, in some embodiments, after the SOT line is patterned, a second mask (Mask 2) may be provided on the SOT line using negative-tone resist, as illustrated in FIG. 19D. As illustrated in FIG. 19E, the MTJ pillar may be patterned with E-beam lithography (EBL) based on the second mask by two-step ion-beam etching with in-situ passivation via Al₂O₃ sputtering and resist liftoff. The etching of the MTJ pillar may stop at the SOT line and the surface of the MTJ pillar, respectively, using accurate time control or endpoint detection via secondary ion mass spectrometry, similar to the SOT line.

A first electrode may be formed on the MTJ pillar and a second electrode may be formed on a portion of the SOT line (S50). For example, as illustrated in FIG. 19F, in some embodiments, an insulating material may be deposited on the SOT line and the MTJ pillar and then etched to expose the top layer of the MTJ pillar. A third mask (Mask 3) may be disposed on the insulating material using positive-tone resist. As illustrated in FIG. 19G, a top electrode (TE) material (e.g., Cu, Ti(10)/Au(80)) for the MTJ pillar top contact and the SOT line contact may be patterned via EBL and then the positive-tone resist may be evaporated and lifted off to form the top electrodes of the MTJ pillar and the SOT line.

According to an embodiment, a bit cell architecture of the two terminal SOT MRAM devices illustrated in FIGS. 12-15 may use Manhattan routing rules. It is noted that the bit cell architecture is almost identical to a bit cell architecture of a related art STT MRAM (z-type), except with one of the metal layers replaced by the SOT material. The process complexity of such a bit cell architecture is thus comparable to the process complexity of the related art STT MRAM, with an additional process step associated with depositing the SOT material.

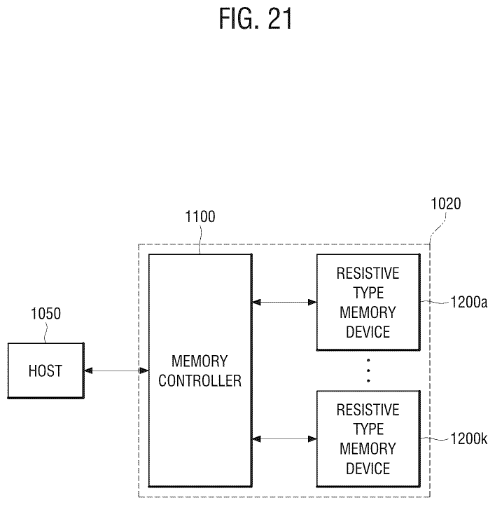

FIG. 21 illustrates a block diagram illustrating an electronic system according to an embodiment.

Referring to FIG. 21, an electronic system 1000 may include a host 1015 and a memory system 1020. The memory system 1020 may include a memory controller 1100 and a plurality of resistive memory devices 1200a to 1200k.

The host 1015 may communicate with the memory system 1020 through various interface protocols such as Peripheral Component Interconnect-Express (PCI-E), Advanced Technology Attachment (ATA), Serial ATA (SATA), Parallel ATA (PATA), or serial attached SCSI (SAS). In an embodiment, the host 1015 may communicate with the memory system 1020 through interface protocols such as Universal Serial Bus (USB), Multi-Media Card (MMC), Enhanced Small Disk Interface (ESDI), or Integrated Drive Electronics (IDE).

The memory controller 1100 may control an overall operation of the memory system 1020. The memory controller 1100 may control an overall data exchange between the host 1015 and the plurality of resistive memory devices 1200a to 1200k. For example, the memory controller 1100 may write data in the plurality of resistive memory devices 1200a to 1200k or read data from the plurality of resistive memory devices 1200a to 1200k in response to request from the host 1015.

In an embodiment, the memory controller 1100 may issue operation commands to the plurality of resistive memory devices 1200a to 1200k for controlling the plurality of resistive memory devices 1200a to 1200k.

In some embodiments, each of the plurality of resistive memory devices 1200a to 1200k may comprise one of the two terminal SOT MRAM devices according to various embodiments described above with reference to FIGS. 1-18.

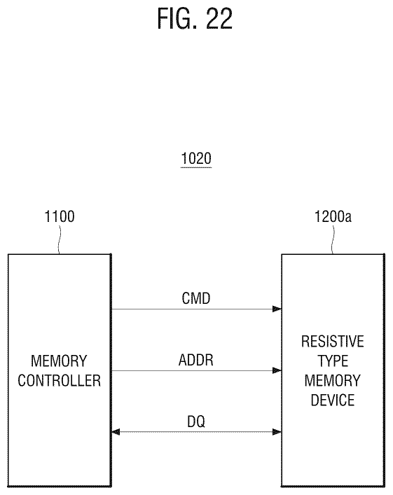

FIG. 22 illustrates a block diagram illustrating the memory device 1020 of the electronic system 1000 of FIG. 21, according to an embodiment.

In FIG. 22, only one resistive type memory device 1200a in communication with the memory controller 1100 is illustrated for convenience. However, the details discussed herein related to resistive type memory device 1200a may equally apply to the other resistive type memory devices 1200b to 1200k.

Referring to FIG. 22, the memory system 1020 may include the memory controller 1100 and the resistive type memory device 1200a. The memory controller 1100 may transmit command CMD and address ADDR to the resistive type memory device 1200a. The memory controller 1100 may exchange data DQ with the resistive type memory device 1200a.

Referring to FIGS. 21 and 12, the memory controller 1100 may input data to the resistive type memory device 1200a or may output data from the resistive type memory device 1200a based on the request from the host 1015.

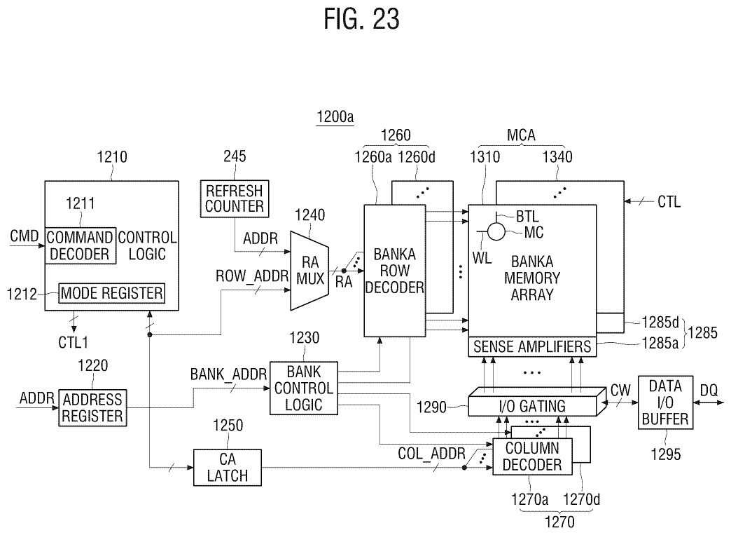

FIG. 23 illustrates a block diagram of the resistive type memory device 1200a in the memory system 1020 of FIG. 22, according to some embodiments.

Referring to FIG. 3, the resistive type memory device 1200a may include a control logic 1210, an address register 1220, a bank control logic 1230, a row address multiplexer 1240, a column address latch 1250, a row decoder 1260, a column decoder 1270, a memory cell array 1300, a sense amplifier circuit 1285, an input/output (I/O) gating circuit 1290, a data input/output (I/O) buffer 1295, and a refresh counter 1245.

The memory cell array 1300 may include first through eighth bank arrays 1310 to 1340. The row decoder 1260 may include first through fourth bank row decoders 1260a to 1260d respectively coupled to the first through fourth bank arrays 1310 to 1340, the column decoder 1270 may include first through fourth bank column decoders 1270a to 1270d respectively coupled to the first through fourth bank arrays 1310 to 1340, and the sense amplifier unit 1285 may include first through fourth bank sense amplifiers 1285a to 1285d respectively coupled to the first through fourth bank arrays 1310 to 1340. The first through fourth bank arrays 1310 to 1340, the first through fourth bank row decoders 1260a to 1260d, the first through fourth bank column decoders 1270a to 1270d and first through fourth bank sense amplifiers 1285a to 1285d may form first through fourth banks. Each of the first through fourth bank arrays 1310 to 1340 may include a plurality of resistive type memory cells RMC, and each of resistive type memory cells RMC is coupled to a corresponding word-line and a corresponding bit-line. Although the resistive type memory device 1200a is illustrated in FIG. 23 as including four banks, the resistive type memory device 1200a may include any number of banks. In some embodiments, the different banks, as well as row and column decoders, may be formed on a single semiconductor chip (e.g., a die formed from a wafer). In other embodiments, each group of a different bank, row decoder, and column decoder (or different sets of groups) may be formed on a plurality of different respective semiconductor chips, such as a stack of semiconductor chips.

The address register 1220 may receive an address ADDR including a bank address BANK_ADDR, a row address ROW_ADDR and a column address COL_ADDR from the memory controller 1100. The address register 1220 may provide the received bank address BANK ADDR to the bank control logic 1230, may provide the received row address ROW ADDR to the row address multiplexer 1240, and may provide the received column address COL_ADDR to the column address latch 1250.

The bank control logic 1230 may generate bank control signals in response to the bank address BANK_ADDR. One of the first through fourth bank row decoders 1260a to 1260d corresponding to the bank address BANK_ADDR may be activated in response to the bank control signals, and one of the first through fourth bank column decoders 1270a to 1270d corresponding to the bank address BANK_ADDR may be activated in response to the bank control signals.

The row address multiplexer 1240 may receive the row address ROW_ADDR from the address register 11220, and may receive a refresh row address REF_ADDR from the refresh counter 245. The row address multiplexer 11240 may selectively output the row address ROW_ADDR or the refresh row address REF_ADDR as a row address RA. The row address RA that is output from the row address multiplexer 240 may be applied to the first through fourth bank row decoders 1260a to 1260d.

The activated one of the first through fourth bank row decoders 1260a to 1260d may decode the row address RA that is output from the row address multiplexer 1240, and may activate a word-line corresponding to the row address RA. For example, the activated bank row decoder may apply a word-line driving voltage to the word-line corresponding to the row address RA.

The column address latch 1250 may receive the column address COL_ADDR from the address register 1220, and may temporarily store the received column address COL_ADDR. In some embodiments, in a burst mode, the column address latch 1250 may generate column addresses that increment from the received column address COL_ADDR. The column address latch 1250 may apply the temporarily stored or generated column address to the first through fourth bank column decoders 1270a to 1270d.

The activated one of the first through fourth bank column decoders 1270a to 1270d may decode the column address COL_ADDR that is output from the column address latch 1250, and may control the input/output gating circuit 1290 in order to output data corresponding to the column address COL_ADDR.

The I/O gating circuit 1290 may include circuitry for gating input/output data. The I/O gating circuit 1290 may further include read data latches for storing data that is output from the first through fourth bank arrays 1310 to 1340, and write drivers for writing data to the first through fourth bank arrays 1310 to 1340.

Data to be read from one bank array of the first through fourth bank arrays 1310 to 1340 may be sensed by a sense amplifier coupled to the one bank array from which the data is to be read, and may be stored in the read data latches. The data DQ stored in the read data latches may be provided to the memory controller 1100 via the data I/O buffer 1295. Data DQ to be written in one bank array of the first through fourth bank arrays 1310 to 1340 may be provided to the data I/O buffer 11295 from the memory controller 100. The write driver may write the data DQ in one bank array of the first through fourth bank arrays 1310 to 1340.

The control logic 1210 may control operations of the resistive type memory device 1200a. For example, the control logic 1210 may generate control signals CTL for the resistive type memory device 1200a in order to perform a write operation or a read operation. The control logic 1210 may include, for example, a command decoder 1211 that decodes a command CMD received from the memory controller 1100 and a mode register 1212 that sets an operation mode of the resistive type memory device 1200a. The mode register 1212 may be programmed by mode register set (MRS) commands. The mode register 1212 may generate mode signals according to a programmed operation mode.

For example, the command decoder 1211 may generate the control signals CTL corresponding to the command CMD by decoding a write enable signal (/WE), a row address strobe signal (/RAS), a column address strobe signal (/CAS), a chip select signal (/CS), etc. The control logic 1210 may provide the control signals CTL to the memory cell array 1300.

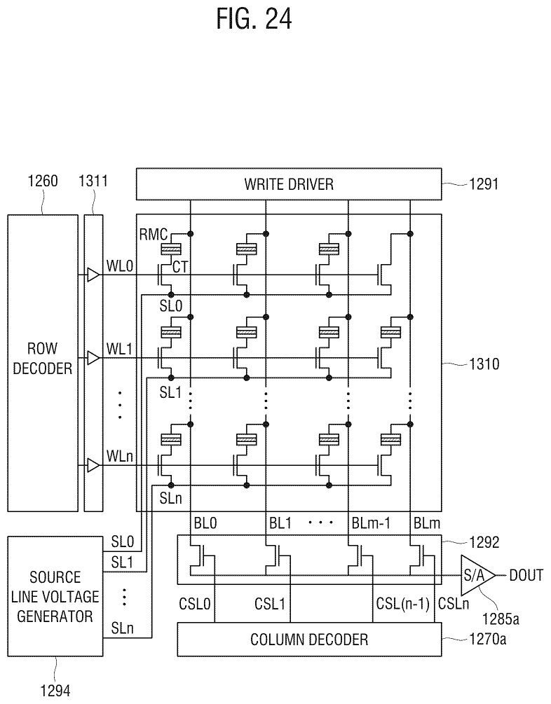

FIG. 24 illustrates an example of a first bank array in the resistive memory device of FIG. 23, according to some embodiments.

Referring to FIG. 24, the first bank array 1310 may include a plurality of word-lines WL0 through WLn (where n is a natural number equal to or greater than 1), a plurality of bit-lines BL0 through BLm (where Mis a natural number equal to or greater than 1), a plurality of source lines SL0 through SLn, and a plurality of resistive type memory cells RMC disposed at intersections between the word-lines WL0 through WLn and the bit-lines BL0 through BLm. Each of the resistive memory cells RMC may be a SOT MRAM cell. For example, the resistive type memory cell RMC may include an MTJ and a SOT material as described in the embodiments above with reference to FIGS. 1-18.

In some embodiments, each of the resistive type memory cells RMC may include a cell transistor CT and the MTJ and the SOT material. In one resistive type memory cell RMC, a drain (a first electrode) of the cell transistor CT may be connected to a pinned layer of the MTJ. A free layer of the MTJ may be connected to SOT material and the SOT material may be connected to the bit-line BL0, and a source (a second electrode) of the cell transistor CT may be connected to the source line SL0. A gate of the cell transistor CT may be connected to the word line WL0. It is noted that this configuration corresponds to the z-type two terminal SOT MRAM device 400 described above with reference to FIG. 12. However, embodiments are not limited thereto and, in some embodiments, the y-type and/or the x-type two terminal SOT MRAM devices 500-700 described above with reference to FIGS. 13-15 may be used with modifications based on the descriptions of FIGS. 13-15.

The word-line WL0 may be enabled by a row decoder 1260, and may be connected to a word line driver 1311 that drives a word-line selection voltage. The word-line selection voltage activates the word-line WL0 in order to read or write a logic state of the MTJ.

The source line SL0 is connected to a source line voltage generator 1294. The source line voltage generator 1294 may receive and decode an address signal and a read/write signal, and may generate a source line selection signal in the selected source line SL0. A ground reference voltage may be supplied to the unselected source lines SLI through SLn.

The bit-line BL0 is connected to a column select circuit 1292 that is driven by column selection signals CSLO through CSLm. The column selection signals CSLO through CSLm are selected by a column decoder 1270a. For example, the selected column selection signal CSLO turns on a column select transistor in the column selection circuit 1292, and selects the bit-line BL0. In an embodiment, a logic state of the MTJ may be read from the bit-line BL0 through a sense amplifier 1285a. In an embodiment, a write current applied through the write driver 1291 may be transmitted to the selected bit-line BL0 and is written to the MTJ.

According to various embodiments, the z-type, y-type or x-type two terminal SOT MRAM with SOT material may be implemented as on-chip nonvolatile memories.

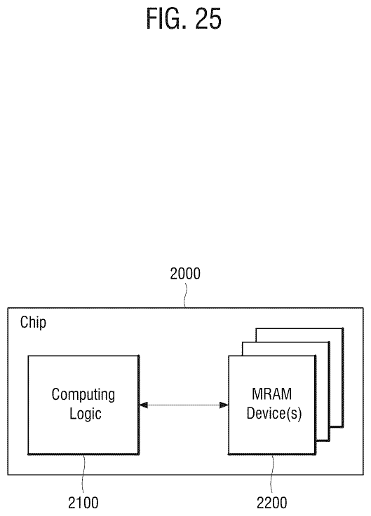

FIG. 25 illustrates a circuit diagram illustrating an example of an on-chip non-volatile memory, according to an embodiment.

The on-chip nonvolatile memory 2000 as illustrated in FIG. 25 may include a semiconductor chip 2000. The semiconductor chip 2000 may include computing logic 2100 and one or more MRAM devices 2200. In some embodiments, the MRAM devices 2200 may each be one or more of the z-type, y-type or x-type two terminal SOT MRAM devices described above with respect to FIGS. 1-18.

The on-chip nonvolatile memory 2000 may provide SRAM-like performance while simultaneously providing a significantly higher bit cell density and a drastic improvement in system-level energy efficiency. Moreover, in some embodiments, the on-chip nonvolatile memory 2000 may be implemented on a satellite or other space related device that is subject to high energy radiation, and the on-chip nonvolatile memory 2000 may prevent soft-errors as described above.

### Exemplary Implementations

Various exemplary implementations are described with reference to the following numerical clauses.

1. A magnetoresistive random access memory (MRAM) device comprising: a magnetic tunnel junction; and a spin-orbit torque material, wherein based on a current applied to the spin-orbit torque material, the spin-orbit torque material generates spin polarization along one or multiple axes.

2. The MRAM device according to clause 1, wherein the spin-orbit torque material is a low symmetry spin-orbit torque material in which the spin polarization, spin current and charge current are not enforced to be orthogonal.

3. The MRAM device according to clause 1 or 2, wherein the magnetic tunnel junction includes a free layer, and the free layer contacts an upper surface of the spin-orbit torque material.

4. The MRAM device according to clause 1 or 2, wherein the magnetic tunnel junction includes a free layer, and the free layer contacts a bottom surface of the spin-orbit torque material.

5. The MRAM device according to clause 1-4, further comprising only two electrodes, a first electrode of the two electrodes being coupled to the magnetic tunnel junction and a second electrode of the two electrodes being coupled to the spin-orbit torque material.

6. The MRAM device according to clause 5, further comprising one or more transistors connected to at least one of the first electrode or the second electrode.

7. The MRAM device according to clause 1-6, wherein the current generates spin-orbit torque and spin-transfer torque.

8. The MRAM device according to clause 1-7, wherein a direction of the current determines one of a parallel state or an antiparallel state as a final state of the MRAM device.

9. The MRAM device according to clause 1-8, wherein a magnitude of the current determines a switching time of the MRAM device.

10. The MRAM device according to clause 1-9, wherein the magnetic tunnel junction has an easy-axis anisotropy in an in-plane orientation with respect to a plane of the spin-orbit torque material.

11. The MRAM device according to clause 10, wherein the current flows through the spin-orbit torque material and generates spins polarized coaxially to the current and/or spins polarized orthogonal to the current, and wherein the current flows through the spin-orbit torque material and generates spins polarized coaxially to the current, generates spins polarized orthogonal to the current in an in-plane orientation with respect to a plane of the spin-orbit torque material, and/or generates spins polarized orthogonal to the current in an out-of-plane orientation with respect to the plane of the spin-orbit torque material.

12. The MRAM device according to clause 1-9, wherein the magnetic tunnel junction has an easy-axis anisotropy in an out-of-plane orientation with respect to a plane of the spin-orbit torque material.

13. The MRAM device according to clause 12, wherein the current flows through the spin-orbit torque material and generates spins polarized coaxially to the current and/or spins polarized orthogonal to the current, and wherein the current flows through the spin-orbit torque material and generates spins polarized coaxially to the current, generates spins polarized orthogonal to the current in an in-plane orientation with respect to the plane of the spin-orbit torque material, and/or generates spins polarized orthogonal to the current in the out-of-plane orientation with respect to the plane of the spin-orbit torque material.

14. The MRAM device according to clause 1-13, wherein the spins generated by the spin-orbit torque material orthogonal to the current in the in-plane orientation are larger than the spins generated by the spin-orbit torque material coaxial to the current and/or orthogonal to the current in the out-of-plane orientation.

15. The MRAM device according to clause 1-9 or 12-14, wherein the magnetic tunnel junction is an out-of-plane magnetic tunnel junction, and wherein, based on the current being applied to the spin-orbit torque material, the MRAM device switches field-free between a parallel state and an antiparallel state.

16. A method of operating the magnetoresistive random access memory (MRAM) device according to clause 1-15, the method comprising: applying the current to the spin-orbit torque material to generate spin polarization along one or multiple axes in the MRAM device.

17. A method of operating the magnetoresistive random access memory (MRAM) device according to clause 1-15, the method comprising: applying the current to the spin-orbit torque material to generate field-free switching in the MRAM device.

18. The method of clause 17, wherein applying the current switches the MRAM device between a parallel state and antiparallel state in the absence of a magnetic bias field and/or an external magnetic field.

19. A magnetoresistive random access memory (MRAM) device comprising: an in-plane magnetic tunnel junction; and a spin-orbit torque material, wherein based on a current being applied to the spin-orbit torque material, the MRAM device switches field-free between a parallel state and an antiparallel state.

20. The MRAM device of clause 19, wherein applying the current switches the MRAM device between the parallel state and the antiparallel state in the absence of a magnetic bias field and/or an external magnetic field.

21. The MRAM device according to clause 19-20, wherein the spin-orbit torque material is a low symmetry spin-orbit torque material in which spin polarization, spin current and charge current are not enforced to be orthogonal.

22. The MRAM device according to clause 19-21, wherein the in-plane magnetic tunnel junction includes a free layer, and the free layer contacts an upper surface of the spin-orbit torque material.

23. The MRAM device according to clause 19-21, wherein the in-plane magnetic tunnel junction includes a free layer, and the free layer contacts a bottom surface of the spin-orbit torque material.

24. The MRAM device according to clause 19-23, further comprising only two electrodes, a first electrode of the two electrodes being coupled to the in-plane magnetic tunnel junction and a second electrode of the two electrodes being coupled to the spin-orbit torque material.

25. The MRAM device according to clause 24, further comprising one or more transistors connected to at least one of the first electrode or the second electrode.

26. The MRAM device according to clause 19-25, wherein the spin-orbit torque material is a conventional spin-orbit torque material which generates spins polarized orthogonal to the current in an in-plane orientation with respect to a plane of the spin-orbit torque material.

27. The MRAM device according to clause 19-25, wherein the spin-orbit torque material is an unconventional spin-orbit torque material which generates spins polarized coaxially to the current, generates spins polarized orthogonal to the current in an in-plane orientation with respect to a plane of the spin-orbit torque material, and/or generates spins polarized orthogonal to the current in an out-of-plane orientation with respect to the plane of the spin-orbit torque material.

28. The MRAM device according to clause 19, wherein a critical dimension of the in-plane magnetic tunnel junction is from about 10 nm to about 43 nm, and the current is from about 80 uA to about 160 uA.

29. A magnetoresistive random access memory (MRAM) device comprising: an out-of-plane magnetic tunnel junction; and a spin-orbit torque material, wherein based on a current being applied to the spin-orbit torque material, the MRAM device switches field-free between a parallel state and an antiparallel state.

30. The MRAM device of clause 29, wherein applying the current switches the MRAM device between the parallel state and the antiparallel state in the absence of a magnetic bias field and/or an external magnetic field.

31. The MRAM device according to clause 29-30, wherein the spin-orbit torque material is a low symmetry spin-orbit torque material in which spin polarization, spin current and charge current are not enforced to be orthogonal.

32. The MRAM device according to clause 29-31, wherein the out-of-plane magnetic tunnel junction includes a free layer, and the free layer contacts an upper surface of the spin-orbit torque material.

33. The MRAM device according to clause 29-31, wherein the out-of-plane magnetic tunnel junction includes a free layer, and the free layer contacts a bottom surface of the spin-orbit torque material.

34. The MRAM device according to clause 29-33, further comprising only two electrodes, a first electrode of the two electrodes being coupled to the out-of-plane magnetic tunnel junction and a second electrode of the two electrodes being coupled to the spin-orbit torque material

35. The MRAM device according to clause 34, further comprising one or more transistors connected to at least one of the first electrode or the second electrode.

36. The MRAM device according to clause 29-35, wherein the spin-orbit torque material is a conventional spin-orbit torque material which generates spins polarized orthogonal to the current in an in-plane orientation with respect to a plane of the spin-orbit torque material.

37. The MRAM device according to clause 29-35, wherein the spin-orbit torque material is an unconventional spin-orbit torque material which generates spins polarized coaxially to the current, generates spins polarized orthogonal to the current in an in-plane orientation with respect to a plane of the spin-orbit torque material, and/or generates spins polarized orthogonal to the current in an out-of-plane orientation with respect to the plane of the spin-orbit torque material.

38. A method of manufacturing a two terminal spin-orbit torque (SOT) magnetoresistive random access memory (MRAM) device, the method comprising: depositing a spin-orbit torque (SOT) material on a substrate; depositing a magnetic tunnel junction (MTJ) stack on the SOT material; forming a SOT line from the SOT material; forming an MTJ pillar from the MTJ stack; and forming a first electrode on the MTJ pillar and a second electrode on a portion of the SOT line.

39. The method according to clause 38, wherein the spin-orbit torque material is a low symmetry spin-orbit torque material in which spin polarization, spin current and charge current are not enforced to be orthogonal.

40. The method according to clause 38-39, wherein forming the SOT line comprises: depositing a mask on the MTJ stack; and patterning the SOT line based on the mask;

41. The method according to clause 38-40, wherein the SOT line is patterned with E-beam lithography (EBL) based on the mask by two-step ion-beam etching.

42. The method according to clause 38-41, wherein forming the MTJ pillar comprises: depositing a mask on the SOT line; and patterning the MTJ pillar based on the mask

43. The method according to clause 38-42, wherein the MTJ pillar is patterned with E-beam lithography (EBL) based on the mask by two-step ion-beam etching.

44. The method according to clause 38-43, wherein forming the first electrode and the second electrode comprises: depositing an insulating material on the SOT line and the MTJ pillar and etching the insulating material to expose a top layer of the MTJ pillar; depositing a mask on the insulating material; and patterning, based on the mask, a top electrode material over the top layer of the MTJ pillar and over the portion of the top layer of the SOT line to form the first electrode connected to the MTJ pillar and the second electrode connected to the SOT line.

45. The method according to clause 38-44, wherein the MTJ stack has a low resistance area product.

46. The method according to clause 38-45, wherein the MTJ stack is deposited via magnetron sputtering on a surface-passivated CMOS die.

47. The method according to clause 37-45, wherein a minimum width of the SOT line is be about 5 nm to about 30 nm.

48. The method according to clause 38-47, wherein the top electrode material comprises at least one of Cu, Ti or Au.

Applications of the above-described technology include, but are not limited to, magnetoresistive random access memory (MRAM), including SOT MRAM and STT MRAM, Last Level Cache Applications, Edge Computing applications, and/or Internet of Things (IOT) Applications.

The two terminal SOT MRAM device according to various embodiments described above provides advantages including, but not limited to: 1)>2× write current reduction compared to related art STT MRAM technologies; 2) 4× faster than related art STT MRAM technologies; 3) Ultrahigh density physical layout (as low as −12F\hat{ }2 per magnetic tunnel junction (MTJ), where F denotes a minimum half-pitch feature size of a chip layout), which is about 4× to 8× denser than 6T SRAM technology, owing to the one transistor, one resistor (1TIR) bit cell layout; 4) Writing scheme supports all types of SOT switching, including x-type, y-type and z-type; 5) SRAM-like performance, with close to an order of magnitude improvement in bit cell density with ultralow leakage current; 6) CMOS compatible—the MRAM can be integrated for BEOL (back end of line) processing below 400 C thermal budget; and/or 7) Energy-efficient, nonvolatile data storage. However, embodiments are not limited to these advantages and some embodiments may provide additional improvements not discussed above.

It should be understood that embodiments are not limited to the various embodiments described above, but various other changes and modifications may be made therein without departing from the spirit and scope thereof as set forth in appended claims.

1. A magnetoresistive random access memory (MRAM) device comprising:
a magnetic tunnel junction; and
a spin-orbit torque material,
wherein based on a current applied to the spin-orbit torque material, the spin-orbit torque material generates spin polarization along one or multiple axes.

2. The MRAM device according to claim 1, wherein the spin-orbit torque material is a low symmetry spin-orbit torque material in which the spin polarization, spin current and charge current are not enforced to be orthogonal.

3. The MRAM device according to claim 1, wherein the magnetic tunnel junction includes a free layer, and the free layer contacts an upper surface of the spin-orbit torque material.

4. The MRAM device according to claim 1, wherein the magnetic tunnel junction includes a free layer, and the free layer contacts a bottom surface of the spin-orbit torque material.

5. The MRAM device according to claim 1, further comprising only two electrodes, a first electrode of the two electrodes being coupled to the magnetic tunnel junction and a second electrode of the two electrodes being coupled to the spin-orbit torque material.

6. (canceled)

7. The MRAM device according to claim 1, wherein the current generates spin-orbit torque and spin-transfer torque.

8. The MRAM device according to claim 7, wherein a direction of the current determines one of a parallel state or an antiparallel state as a final state of the MRAM device.

9. The MRAM device according to claim 7, wherein a magnitude of the current determines a switching time of the MRAM device.

10. (canceled)

11. The MRAM device according to claim 1, wherein the current flows through the spin-orbit torque material and generates spins polarized coaxially to the current and/or spins polarized orthogonal to the current, and
wherein the current flows through the spin-orbit torque material and generates spins polarized coaxially to the current, generates spins polarized orthogonal to the current in an in- plane orientation with respect to a plane of the spin-orbit torque material, and/or generates spins polarized orthogonal to the current in an out-of-plane orientation with respect to the plane of the spin-orbit torque material.

12-14. (canceled)

15. The MRAM device according to claim 1, wherein the magnetic tunnel junction is an out-of-plane magnetic tunnel junction, and
wherein, based on the current being applied to the spin-orbit torque material, the MRAM device switches field-free between a parallel state and an antiparallel state. 16-18. (canceled).

19. A magnetoresistive random access memory (MRAM) device comprising:
an in-plane magnetic tunnel junction; and
a spin-orbit torque material,
wherein based on a current being applied to the spin-orbit torque material, the MRAM device switches field-free between a parallel state and an antiparallel state.

20. The MRAM device of claim 19, wherein applying the current switches the MRAM device between the parallel state and the antiparallel state in the absence of a magnetic bias field and/or an external magnetic field.

21. The MRAM device according to claim 19, wherein the spin-orbit torque material is a low symmetry spin-orbit torque material in which spin polarization, spin current and charge current are not enforced to be orthogonal.

22. The MRAM device according to claim 19, wherein the in-plane magnetic tunnel junction includes a free layer, and the free layer contacts an upper surface of the spin-orbit torque material.

23. The MRAM device according to claim 19, wherein the in-plane magnetic tunnel junction includes a free layer, and the free layer contacts a bottom surface of the spin-orbit torque material.

24. The MRAM device according to claim 19, further comprising only two electrodes, a first electrode of the two electrodes being coupled to the in-plane magnetic tunnel junction and a second electrode of the two electrodes being coupled to the spin-orbit torque material.

25. The MRAM device according to claim 24, further comprising one or more transistors connected to at least one of the first electrode or the second electrode.

26. The MRAM device according to claim 19, wherein the spin-orbit torque material is a conventional spin-orbit torque material which generates spins polarized orthogonal to the current in an in-plane orientation with respect to a plane of the spin-orbit torque material.

27. The MRAM device according to claim 19, wherein the spin-orbit torque material is an unconventional spin-orbit torque material which generates spins polarized coaxially to the current, generates spins polarized orthogonal to the current in an in-plane orientation with respect to a plane of the spin-orbit torque material, and/or generates spins polarized orthogonal to the current in an out-of-plane orientation with respect to the plane of the spin-orbit torque material.

28. (canceled)

29. A magnetoresistive random access memory (MRAM) device comprising:
an out-of-plane magnetic tunnel junction; and
a spin-orbit torque material,
wherein based on a current being applied to the spin-orbit torque material, the MRAM device switches field-free between a parallel state and an antiparallel state.

30-48. (canceled)
